(19) United States
(12) Patent Application Publication
(10) Pub. No.: US 2026/0282617 A1
(43) Pub. Date: Sep. 17, 2026

(54) LIGHT-EMITTING ELEMENT WITH STANDING WAVE GENERATOR AND ASSOCIATED OPTOELECTRONIC DEVICE

(71) Applicant: ALEDIA, Echirolles (FR)

(72) Inventors: Mehdi DAANOUNE, Renage (FR); Tiphaine DUPONT, Grenoble (FR)

(21) Appl. No.: 18/876,547

(22) PCT Filed: Jun. 19, 2023
(86) PCT No.: PCT/EP2023/066490

§ 371 Date: Dec. 18, 2024

(30) Foreign Application Priority Data
Jun. 20, 2022 (FR) FR2206016

(51) Int. Cl. H10H 20/851; H10H 20/80; H10H 20/812

(52) U.S. Cl. CPC H10H 20/8511; H10H 20/812; H10H 20/872

(57) ABSTRACT

The present invention relates to light-emitting element (10) including:
a conversion material (14) suitable for converting a first radiation within a first spectral band into a second radiation within a second spectral band, the second spectral band being distinct from the first spectral band, and
a standing wave generator within the first spectral band, the standing wave generator including a two-dimensional photonic crystal (26) suitable for generating a standing wave within the first spectral band, the photonic crystal (26) being formed at least in part by light-emitting diodes (12) suitable for emitting within the first spectral band.

### FIELD OF THE INVENTION

The present invention relates to a light-emitting element and an optoelectronic device including such a light-emitting element.

### TECHNOLOGICAL BACKGROUND OF THE INVENTION

In the field of optoelectronics, the production of very small devices is desired. In particular, such is the case for pixels for color displays.

In color displays, each pixel comprises a plurality of subpixels, each subpixel being configured for emitting a specific color, so that the color emitted by the pixel can be changed by controlling which sub-pixel(s) is (are) activated or by changing the electrical current applied to each sub-pixel in order to change the relative emission intensity of each sub-pixel.

Semiconductor structures such as light-emitting diodes (LEDs) are commonly used for various purposes, such as lighting, due to the potential good efficiency thereof for light emission. Due to such potential high efficiency, LEDs have been suggested for the manufacture of high efficiency displays. LED structures usually take the form of a stack of planar semiconductor layers. Light is emitted when an electric current flows through the stack.

Thereby, to reduce the size of the pixels, it is known how to grow native pixels containing LEDs made of GaN/InGaN on the same wafer. A native pixel is a pixel the emission of which is natively of the desired color.

However, such pixels are not efficient because only the quantum efficiency of such type of LED for the color blue is satisfactory. In fact, the quantum efficiency for green color is generally 30% whereas, for red color, same falls to less than 5%.

Therefore, it is known how to use color conversion modules for obtaining other colors from a blue or an UV LED. Quantum dots are common examples of converters used in the conversion modules. Quantum dots are often inserted into a matrix.

However, for pixels on the order of a few micrometers, the absorption of the quantum dots is too low to guarantee a complete conversion of blue radiation to red or green radiation. It results therefrom that the unconverted radiation has to be filtered in order to obtain a red or green pixel. Such filtering represents a significant loss of the radiation emitted by the LED. E.g., a loss of 60% is observed for a pixel with a size of 5 μm by 5 μm.

It could be envisaged to compensate for such loss by increasing the number of quantum dots. A first way to increase the number of quantum dots is to increase the concentration of quantum dots in the matrix. Such proposition comes up against the fact that too high concentrations lead to losses in the mechanical properties of the matrix, making same incompatible with the techniques used in the fabrication of the pixel.

A second way to increase the number of quantum dots is to increase the size of the matrix and in particular the thickness thereof.

However, there again, such increase comes up against a plurality of problems.

First of all, the fabrication of pixels with a very high thickness is technically difficult.

A thicker matrix means a longer optical path length of the radiation converted by the quantum dots. Such increase results in greater reabsorption losses.

Another problem is related to the existence of crosstalk between two pixels. Crosstalk is usually prevented by inserting opaque walls on the edges of the color conversion module. A greater thickness of the matrix involves an increase in the height of the walls and hence higher absorption losses at the larger walls and even so high that the losses exceed the absorption gain associated with the increase in the number of quantum dots.

### SUMMARY OF THE INVENTION

There is thus a need for a light-emitting element of small size for overcoming the aforementioned drawbacks.

To this end, the description describes a light-emitting element including a conversion material suitable for converting a first radiation within a first spectral band into a second radiation within a second spectral band, the second spectral band being distinct from the first spectral band. The light-emitting element further comprises a standing wave generator within the first spectral band, the standing wave generator comprising a two-dimensional photonic crystal suitable for generating a standing wave within the first spectral band, the photonic crystal being formed at least in part by light-emitting diodes suitable for emitting within the first spectral band.

Contrary to the state of the art, and in particular documents FR 3 068 173 A and US 2022/102 324 A1, the nanowires forming the light-emitting source are part of the photonic crystal and are used to produce it in part. More precisely, the photonic crystal here is the combination of a medium and nanowires.

In addition, the photonic crystal has a different role since it serves to generate a standing wave that is generated efficiently thanks to the difference in the previous structure.

In this way it is possible to produce light-emitting elements, generally pixels, which are small and have good conversion efficiency and thus emit a satisfactory amount of light.

According to other particular embodiments, the light-emitting element has one or a plurality of the following features, taken individually or according to all technically possible combinations:
the photonic crystal is formed solely by light-emitting diodes and a medium surrounding the light-emitting diodes.
the light-emitting diodes comprise an active layer, at least one active layer being included in the photonic crystal. This allows efficient injection of light into the photonic crystal to form the standing wave.
the photonic crystal is partly formed from each active layer of the light-emitting diodes.
the photonic crystal includes all of each light-emitting diode.
the light-emitting diodes are in a medium, said medium being the conversion material. The above is used for reducing the light-emitting element.
the conversion material is based on the photonic crystal. The above facilitates the fabrication of the light-emitting element.
the photonic crystal has a plurality of band gaps, the photonic crystal having a pitch and a filling factor suitable for making the light-emitting diodes emit at 90° on the band edge of the first band gap. The above increases the probability of absorption of photons within the first spectral band by the conversion material.
the photonic crystal has several band gaps, the photonic crystal having a pitch and a filling factor suitable for making the light-emitting diodes emit at 90° on the band edge of a band gap which is different from the first band gap. In this way it is possible to obtain a better efficiency of the light-emitting element by increasing the directionality of the converted radiation.
the pitch and the filling factor of the photonic crystal are also suitable for making the conversion material emit on the band edge of a 0° band gap, the band gap wherein the conversion material emits being smaller than the band gap wherein the light-emitting diodes emit. The above makes it possible to obtain a more accurate perpendicular directional emission for the photonic crystal, resulting in better performance of the light-emitting element.
the photonic crystal is surrounded by walls forming a cavity, at least one of the walls being made of a material selected from the list consisting of a transparent conductive oxide such as indium tin oxide or a zinc oxide doped with gallium or aluminum, a metal such as Ag or Al, graphene and a combination of said elements. In this way it is possible to obtain walls with good optical properties and thus improve the efficiency of the photonic crystal.
the conversion material is a polymer matrix comprising quantum dots. The above facilitates the fabrication of the light-emitting element.
each light-emitting diode includes an active medium made of a first material surrounded by layers made of a second material, the first material comprising InGaN, and the second material comprising GaN. In this way it is possible to obtain good performances of the light-emitting element while maintaining an easy fabrication.
the photonic crystal includes a central part and a peripheral part, each part bringing together a set of light-emitting diodes, only the central part of the photonic crystal being supplied with energy. In this way it is possible to reduce energy consumption.

The description also relates to a light-emitting element comprising light-emitting diodes adapted to emit in a spectral band and comprising an active layer and a two-dimensional photonic crystal formed at least from a medium and active layers of the light-emitting diodes, the crystal being adapted to generate a standing wave in the spectral band.

Otherwise formulated, the description proposes a light-emitting element comprising a two-dimensional photonic crystal adapted to generate a standing wave, the photonic crystal comprising the emitting sources of the light-emitting element.

The description also describes an optoelectronic device comprising at least one light-emitting element as described above.

### BRIEF DESCRIPTION OF DRAWINGS

The features and advantages of the invention will appear upon reading the following description, given only as an example, but not limited to, and making reference to the enclosed drawings, wherein:

FIG. 1 is a schematic cross-section representation of an example of a pixel,

FIG. 2 is a schematic representation of a band diagram illustrating an example of how the pixel shown in FIG. 1 works,

FIG. 3 is a schematic representation of the radiation emitted by certain elements of the pixel within the framework of the functioning shown in FIG. 2,

FIG. 4 is a schematic representation of another example of pixel,

FIG. 5 is a schematic representation of a band diagram illustrating another example of how the pixel shown in FIG. 1 works,

FIG. 6 is a schematic representation of the radiation emitted by certain elements of the pixel within the framework of the functioning of the figure, and

FIG. 7 is a top view schematic representation of another example of pixel.

### DETAILED DESCRIPTION OF PREFERRED EMBODIMENTS

Hereinafter, to facilitate understanding, the present invention will be explained as follows: first by explaining the general principles thereof through a specific example, and then, secondly, by giving details of how the same principles can be easily applied to other examples. Thirdly, refinements or alternative embodiments of the examples will be described.

Furthermore, to simplify the description, a “definitions” section has been inserted at the end and the reader is invited to refer thereto for each of the terms introduced hereinafter.

### Presentation of a Specific Example

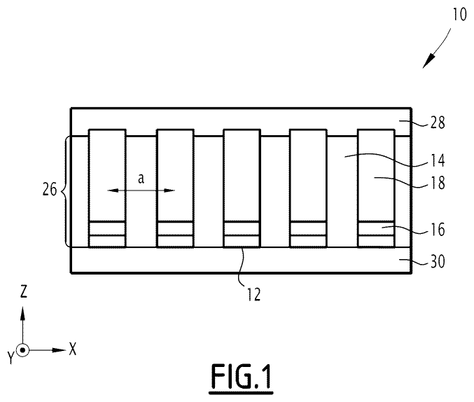

With regard to the specific example, it is proposed with reference to FIG. 1, to consider the case of a red subpixel 10, simply called hereinafter red pixel 10 (for simplicity).

In the case of FIG. 1, the red radiation of the pixel 10 is obtained by a conversion of a blue radiation from nanowires 12 using a conversion material 14.

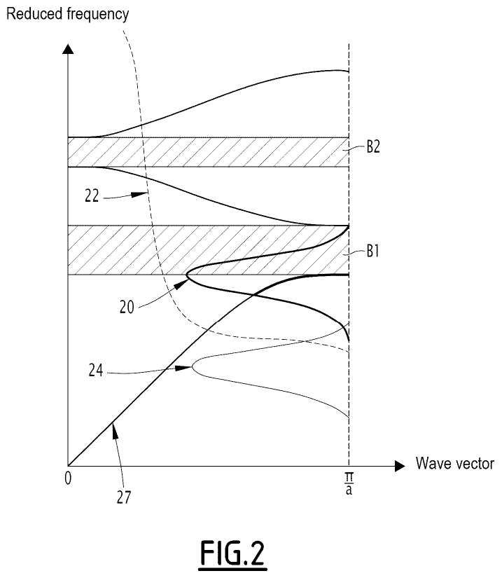

The nanowires 12 are light-emitting diodes made of a material comprising InGaN, for forming the active layer 16 between layers of GaN 18, typically of nGaN or of pGaN. The nanowires 12 emit blue radiation. The emission spectrum 20 from a nanowire 12 is visible in the band diagram shown in FIG. 2.

The nanowires 12 extend mainly along a longitudinal direction Z. The transverse directions are called first transverse direction X and second transverse direction Y, respectively.

For the present example, the conversion material 14 is a matrix comprising quantum dots. Each quantum dot has the absorption spectrum 22 and the emission spectrum 24 which are illustrated in the band diagram in FIG. 2.

The set of nanowires 12 is arranged in the conversion material 14 so as to form a photonic crystal 26 of pitch a.

Since such arrangement of the nanowires 12 is two-dimensional, the photonic crystal 26 is a two-dimensional photonic crystal.

The photonic crystal 26 forms a resonant cavity in a plane formed by the two transverse directions X and Y, denoted as transverse plane XY hereinafter.

The emission curves 27 of the photonic crystal 26 corresponding to each propagation mode allowed by the photonic crystal 26 are shown diagrammatically on the band diagram of FIG. 2. The emission curves 27 are curves representing the wavelength emitted as a function of the emission angle.

The propagation modes of the photonic crystal 26 are separated by band gaps. In FIG. 2, two band gaps B1 and B2 are shown schematically.

The position of the two band gaps B1 and B2 is determined by the pitch a of the photonic crystal 26, the diameter of the nanowires 12, the indices of the materials of the nanowires 12 and of the conversion material 14, as well as the total thickness of the photonic crystal 26.

Furthermore, the photonic crystal 26 is surrounded by two walls 28 and 30, namely an upper wall 28 and a lower wall 30, the two walls 28 and 30 forming a cavity along the longitudinal direction Z.

One of the two walls 28 and 30 is a wall making the extraction of light possible whereas the other wall is a reflecting wall.

In order to produce the walls 28 and 30, it is possible to envisage a stack of layers of different materials, the materials being metals and/or dielectrics. Advantageously, a conductive material such as indium tin oxide (also called ITO), a metal such as Ag or Al is in direct contact with the upper and the lower part of the nanowires 12 so as to make possible electrical injection.

In fact, the photonic crystal 26 has herein, the particularity of forming a blue standing wave generator in the transverse XY plane for wavelengths close to the band gaps at 90°.

By the term “generator”, it should be understood that the photonic crystal 26 is herein a primary source in the sense that the standing wave is created within the photonic crystal 26 as such. More particularly, a radiation sent onto such a photonic crystal does not make the creation of a standing wave possible, the penetration of the radiation into the photonic crystal 26 being very low.

Such particularity is now explained by discussing the physical phenomena involved, in detail.

In the standing wave generator, the Purcell effect increases the rate of spontaneous photon emission for a material in a resonant cavity compared to a material which is not in a resonant cavity. The above means that the nanowires 12 emit more photons in the transverse plane XY. Thereby, an angular and wavelength selection results from the Purcell effect.

In the example described, the photonic crystal 26 works on a specific band edge, namely the band edge at 90° (corresponding to a wave vector of π/a) of the first resonance band of a nanowire 12. A band edge corresponds to a range of wavelengths for which the emission curve 27 of the photonic crystal flattens significantly, typically over a range of wavelengths less than 25 nm, advantageously less than 10 nm and advantageously still less than 5 nm. With reference to FIG. 2, the above means that the emission takes place on the first resonance band of a nanowire 12 on the part of the first resonance band shown with a thicker line.

More precisely, the emission finally produced by the nanowire 12 in the photonic crystal 26 is limited to the intersection portion between the emission spectrum 20 (primary emission) and the emission curve 27 of the photonic crystal 26 situated below the first band gap B1, i.e. an angular emission according to the thicker line portion which is mainly at 90° (corresponding to the generation of a standing wave).

The consequence therefrom is to constrain the emission of radiation in the photonic crystal 26 only in the XY plane.

The photonic crystal 26 is thereby suitable for generating a standing wave in the blue [range], the photonic crystal 26 being formed at least in part by nanowires 12 suitable for emitting in the blue [range].

Obtaining such a behavior of the photonic crystal 26 presupposes adapting the elementary unit cell, the pitch and the filling factor of the photonic crystal.

The elementary lattice and the pitch of the photonic crystal 26 correspond to the arrangement of the nanowires 12 whereas the filling factor is the ratio between the surface area occupied by the nanowires 12 and the total surface area of the photonic crystal 26 and depends as such on the size of the nanowires 12 and more precisely, herein, on the diameter thereof.

To choose an appropriate arrangement and diameter for the nanowires 12, it is possible to use the simulation technique for a configuration which is easy to carry out experimentally, and a homothety is then used.

E.g. the applicant ran a test with a photonic crystal emitting at 0.52 μm and having a hexagonal lattice, a filling factor of 50% and extending over 1.5 μm. The above led the applicant to determine that the band edge was situated at the reduced frequency of 0.43. By definition, the reduced frequency is the ratio between the pitch a and the wavelength.

In this way it is possible to determine that, for an emission at 450 nm, the appropriate pitch a is 193.5 nm.

It is then possible to perform a numerical simulation. The applicant has thus shown that it is possible to obtain an absorption of 96% with quantum dots having an encapsulation material having an index of 1.55 whereas the pixel has a size of only 1.5 μm by 1.5 μm. In addition, absorption takes place over a relatively wide band of about 30 nm centered around the reduced frequency of 0.43.

Thereby, by reformulating what has just been indicated, by a simple choice of the arrangement of the nanowires 12 and the diameter thereof, the blue radiation emitted by the nanowires 12 is forced to move in the transverse plane XY so that a standing wave forms within the conversion material 14.

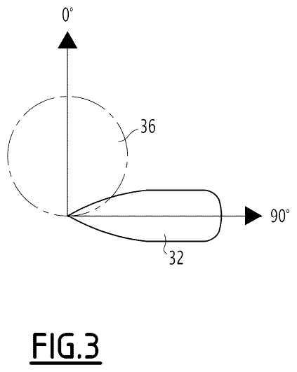

There is thus no blue radiation in another direction so that the radiation is no longer Lambertian. The above clearly appears in FIG. 3 which schematically represents the blue radiation emitted by the nanowires under the numerical reference 32.

It results therefrom that the presence of the photonic crystal 26 considerably increases the length of the optical path traveled by the photons emitted by the nanowires 12 in the conversion material 14 since the photons make round trips in the conversion material 14.

Such increase in the optical path leads to a higher probability that a blue photon encounters a quantum dot, resulting in a considerable increase in the absorption of blue radiation by the quantum dots. The absorption of all the light emitted by each nanowire 12 becomes almost total.

Along the longitudinal direction Z, the emission of a red radiation presenting the emission of a Lambertian is obtained, as shown in FIG. 3 in dotted lines, with the reference sign 36.

More particularly, by design, the thickness of each quantum dot is very small and thus the path of the converted light in the conversion material 14 is very small. The above significantly prevents reabsorption losses.

It results therefrom that, compared with an increase in the thickness of the conversion material, a very large increase in the absorption by the quantum dots is obtained without any increase in the reabsorption losses and especially without any increase in the height of the walls.

The quantum efficiency of the proposed pixel 10 is thereby considerably increased.

A consequence of such good quantum efficiency is that, unlike known conversion modules, the leakage of blue photons becomes low so that the blue radiation cut-off filter has a reduced thickness or is no longer indispensable if the diffusion is negligible.

Also, in case of a suitable quantum efficiency, it can even be envisaged to reduce the quantity of quantum dots in the matrix. Such a reduction would reduce the fabrication cost of the pixel 10 and the quantity of materials harmful to the environment.

Furthermore, the fabrication of the pixel 10 is easier than the fabrication of other known pixels, in particular insofar as fewer elements are needed, such as e.g. the presence of a blue filter or of high walls to prevent crosstalk.

In addition, the fabrication can involve relatively standard techniques compatible with small size pixels 10.

### Extension of the Principle to Other Examples

The principle of using a standing wave generator for improving the conversion of a pixel 10 can have versions for many other examples without changing the principle.

In particular, what has just been described remains valid for other wavelengths.

In particular, the red pixel 10 can be a green pixel.

The radiation emitted by the nanowires 12 can be ultraviolet radiation.

The principle is also compatible with other conversion materials 14.

A list of possible materials can be found in the section on definitions.

The materials used for forming the nanowires can also be different from the pair GaN and InGaN.

In particular, it is possible to envisage a semiconductor material including predominantly at least one element of group Ill and one element of group V (e.g. gallium nitride GaN), hereinafter referred to as III-V compound, or including predominantly at least one element from group II and one element from group VI (e.g. zinc oxide ZnO), hereinafter called compound II-VI, or including predominantly at least one element from group IV.

It is also known how to produce an active zone comprising means of confinement, in particular a single quantum well or multiple quantum wells. A single quantum well is produced by interposing, between two layers of a first semiconductor material, e.g. a III-V compound, in particular GaN, p-type doped or n-type, respectively, a layer of a second semiconductor material, e.g. an alloy of the III-V compound and of a third element, in particular InGaN, the band gap of which is different from the first semiconductor material. A multiple quantum well structure comprises a stack of semiconductor layers forming an alternation of quantum wells and of barrier layers.

Other materials can also be envisaged for producing the upper 28 or lower 30 walls.

Thereby, the upper wall 28 is made of a zinc oxide doped with gallium or aluminum (also called ZNO).

More generally, the upper wall 28 is made of Transparent Conductive Oxide (more often referred to by the abbreviation TCO.

However, other materials such as graphene can be considered.

The same materials can be used for the bottom wall 30.

### Refinements or Alternative Embodiments

Refinements or alternative embodiments are now proposed.

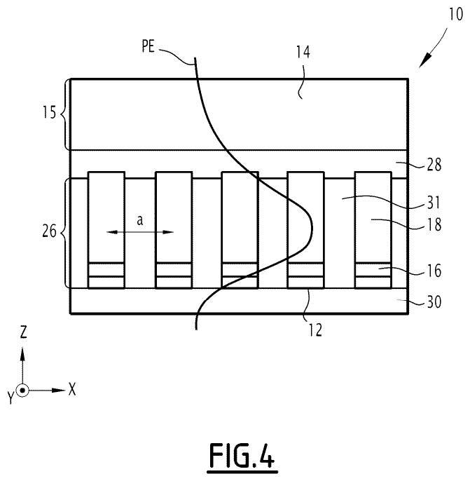

With reference to FIG. 4, it is possible to envisage a variant of the red pixel 10 shown in FIG. 1 wherein the conversion material 14 is positioned on the upper wall 28.

The above is achieved in particular by depositing a layer over the entire upper wall. Hereinafter, said layer is called conversion layer 15.

In a variant, it can be envisaged to deposit quantum dots of different colors for adjacent pixels 10. Such a deposit is e.g. obtained using selective lithography or etching techniques.

The medium 31 surrounding the nanowires is then e.g. SiO₂.

In a variant, the medium 31 is TiO₂, Al₂O₃ or Si₃N₄.

More generally, the material forming the medium 31 is an oxide or a nitride transparent to the wavelengths emitted by the nanowires 12 and the quantum dots.

The functioning is nevertheless different from what was described for the case of FIG. 1.

The absorption of the standing wave by the conversion material 14 then occurs on only one part, which is the evanescent part PE of the standing wave which excites the quantum dots of the conversion layer 15.

The evanescent part PE exists because the standing wave has a certain extent along the direction Z.

The above means that the distance between the quantum dots and the nanowires 12 is small enough for the overlap between the PE part of the standing wave and the conversion layer 14 to be large enough.

Furthermore, to advantageously enhance a directional emission of the quantum dots, the distance between the conversion layer 15 and the lower wall 30 is a multiple of A/2n with A being the emission wavelength of a quantum dot and n being the effective index of the set formed by the walls 28 and 30 and the photonic crystal 26.

E.g., the distance can be defined herein as the distance between the center of the conversion layer 15 and the last layer of the bottom wall 30 and obtained by a simulation.

The above improves the red emission by the quantum dot by increasing the number of photons emitted by the Purcell effect as well as the conversion efficiency while making it possible to obtain a more directional emission of the quantum dot.

Such embodiment of a red pixel 10 is less efficient than the embodiment shown in FIG. 1 but allows the conversion layer 15 to be added separately from the generation of blue photons, which makes the process of depositing the layer easier than an incorporation of a conversion matrix between the nanowires.

Furthermore, in such case, one of the last steps of the fabrication process will be the deposition of the conversion layer 15, which means that the quantum dots will undergo fewer technical processes which can affect the performance or the reliability thereof. Moreover, the deposition of a protective layer, in particular against oxidation, can be carried out on the conversion layer 15 in order to increase the reliability thereof. Such a protective layer is e.g. made of SiO₂, TiO₂ or Al₂O₃.

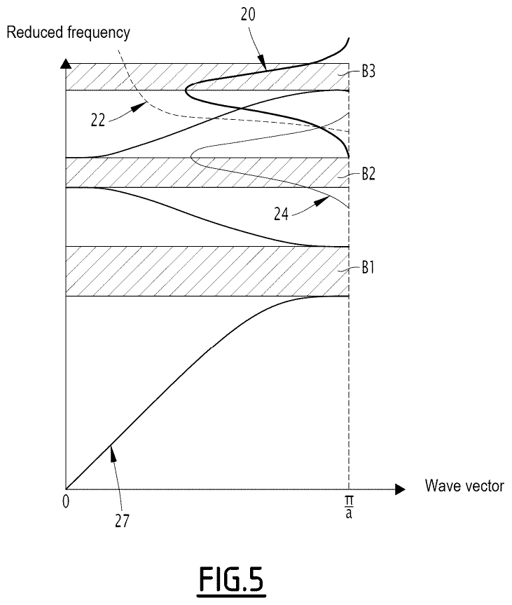

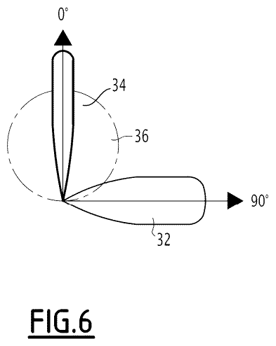

With reference to FIGS. 5 and 6, it is also possible to use a resonance of order n for the emission of the nanowires 12. The above corresponds to using a wave vector of n*π/a instead of π/a.

In such a situation, as can be seen in the band diagram shown in FIG. 5, the wavelength emitted by the quantum dots is aligned with a band edge at 0° (corresponding to the band gap denoted by B2).

Such an alignment can be used for obtaining an increased internal quantum efficiency for the quantum dot (still the aforementioned Purcell effect) and for obtaining a much more directional emission of each quantum dot (more centered on the direction Z).

When the emission spectrum 20 of a nanowire 12 is aligned with a 90° resonance mode (corresponding to the band gap denoted by B3), the preferred emission direction of the nanowire 12 is the transverse plane XY. It can be noted that the band gap wherein the conversion material 14 emits (herein, the band B2) is narrower than the band gap wherein the nanowires 12 emit (herein, the band B3).

In the present case, the emission spectrum of the quantum dots being aligned with a 0° resonance mode, the preferred emission direction for the quantum dots is thus along the direction Z. The above corresponds to the presence of two standing waves, a first of blue color in the transverse plane XY and a second of red color along the axis Z.

The radiation pattern of a quantum dot in such a use of a second order resonance for the emission of nanowires 12 can be seen in FIG. 6.

Thus, advantageously, the photonic crystal 26 having a pitch a and a filling factor suitable for making the nanowires 12 emit on the band edge of a band gap different from the first band gap, herein the third band B3.

Such an embodiment retains the advantages of the embodiment of a red pixel 10 according to FIG. 1 by adding thereto a better directionality of the converted radiation, which contributes to further increasing the efficiency of the pixel 10 considered.

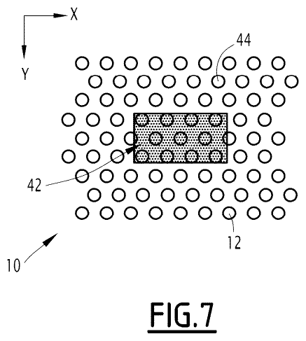

FIG. 7 shows an embodiment which is compatible with all the embodiments which have just been presented for the red pixel 10.

In said example, the photonic crystal 26 includes a central part 42 and a peripheral part 44, each part 42 or 44 gathering together a set of nanowires 14.

The central part 42 is powered and serves for emitting a standing wave, as explained hereinabove.

The peripheral part 44 surrounds the central part 42 and is not powered. The nanowires 12 of the peripheral part 44 then serve as mirrors for the standing wave.

In the peripheral part 44, if it is desired to reflect a plurality of wavelengths, a variable pitch is conceivable, e.g. a pitch increasing from the end towards the central zone.

The above makes it possible to dispense with external mirrors which can also be used in combination, if such combination is desirable.

A set of embodiments has thus been presented, exploiting the idea of using a standing wave generator formed by a photonic crystal, in order to better excite a conversion material. Where it is technically possible, such embodiments can be combined together.

In all cases, it is possible to produce small pixels 10 having a good conversion efficiency and thus emitting a satisfactory amount of light.

The above can be advantageously used for many applications.

More particularly, the pixels can be used for optoelectronic devices such as a display screen, a light projector or further a pair of glasses used for immersion in virtual reality.

In the case of the display screen, the optoelectronic device can be integrated into an electronic device such as a mobile phone, a tablet or a laptop. In another embodiment, the display screen is integrated into a dedicated display device such as a television set or desktop computer monitor.

When the screen is a full color screen, each pixel includes a plurality of pixels of different colors. Such pixels can be the pixels which were just described.

However, it is also possible to envisage a coexistence of pixels according to the prior art, in particular when the efficiency is not as significant (e.g. a screen edge).

### DEFINITIONS

Blue: blue radiation has an average wavelength comprised between 430 nm and 470 nm.

Quantum dot: A quantum dot is a structure wherein quantum confinement occurs in all three spatial dimensions.

An example of a quantum dot is a particle P having a maximum dimension less than or equal to the product of the electron wavelength of the charge carriers in the conversion material, by five.

To give an order of magnitude, a particle P having a maximum dimension comprised between 1 nm and 200 nm and made of a semiconductor converter material is an example of quantum dot.

The quantum dots can be selected from group II-VI, group III-V, group IV-VI semiconductor nanocrystals, or from a mixture thereof.

Group II-VI semiconductor nanocrystals can include, but are not limited to: CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe.

Group III-V semiconductor nanocrystals can include, but are not limited to: GaN, GaP, GaAs, AlN, AlP, AlAs, InN, InP, InAs, InGaN, GaNP, GaNAs, GaPAs, AlNP, AlNAs, AlPAs and InAlPAs.

Group IV-VI semiconductor nanocrystals can include, but are not limited to: SbTe, PbSe, GaSe, PbS, PbTe, SnS, SnTe, PbSnTe. Chalcopyrite semiconductor nanocrystals selected from the group consisting of CuInS2, CuInSe2, CuGaS2, CuGaSe2, AgInS2, AgInSe2, AgGaS2, and AgGaSe2 could also be considered.

Another example of a quantum dot is a particle P having a core and a shell surrounding the core, the core being made of a semiconductor converter material and having a maximum dimension comprised between 1 nm and 200 nm.

The core can comprise e.g. a nanocrystal such as the nanocrystals described hereinabove. The shell can consist of ZnS, CDS, ZnSe, CdSe, or any mixture thereof.

Quantum dots can also be protected against oxidation by using a protective layer of metal oxide, a protective layer of metal nitride, a protective layer of oxynitride or a mixture thereof. A protective layer of metal oxide can be selected from, but not limited to, the group consisting of Al₂O₃, SiO₂, TiO₂, ZrO₂, B₂O₃, CO₂O₃, Cr₂O₃, CuO, Fe₂O₃, Ga₂O₃, HfO₂, In₂O₃, MgO, Nb₂O₅, NiO, SnO₂, and Ta₂O₅.

The metal nitrides can be e.g. BN, AlN, GaN, InN, Zr₃N₄, CuZN, etc.

An oxynitride protective layer could include, but is not limited to, SION.

The thickness of the protective layer can vary from 1 to 400 nm, preferentially from 1 to 100 nm.

The particles P are e.g. incorporated into a photosensitive resin. Photosensitive resins are used in many electronic fabrication techniques for defining patterns on a semiconductor surface, more particularly, since specific zones of the resin can be solidified while leaving the possibility to remove other zones, in order to define the patterns, the zones to be removed or solidified being defined by exposure using a wavelength of light to which the resin is sensitive. Such a photosensitive resin is, more particularly, used for protecting the covered zones against a deposition of material or etching.

It should be noted that the shape of the quantum dot can vary. Examples of quantum dots of different shapes can be called nanorods, nanowires, tetrapods, nanopyramides, nanocubes, etc.

It should be noted that each particle P can comprise more than one quantum dot, e.g. by integrating the quantum dots into a porous silica microsphere, or by aggregating a plurality of quantum dots.

Photonic crystal: a periodic structure of dielectric, semiconductor or metallo-dielectric materials which modifies the propagation of electromagnetic waves in the same way that a periodic potential in a semiconductor crystal affects the movement of electrons by creating allowed and forbidden energy bands. The wavelengths which can propagate in the crystal are called modes, the energy-wave vector representation of which forms bands. The absence of propagating modes of electromagnetic waves in such structures, in a range of frequencies or wavelengths, is then referred to as a band gap.

Band diagram: A band diagram shows the energy of the bands expressed as a function of the reduced frequency as a function of the value of the wave vector.

Light-emitting Diode (LED): A LED structure is a semiconductor structure comprising a plurality of semiconductor regions forming a P-N junction and configured for emitting light when an electric current flows through the different semiconductor zones.

A two-dimensional structure comprising an n-type doped layer, a p-type doped layer and at least one emissive layer, is an example of an LED structure. In such case, each emitting layer is interposed, along the normal direction D, between the n-type doped layer and the p-type doped layer.

In one embodiment, each emissive layer has a band gap value strictly smaller than the band gap value of the n-type doped layer and strictly smaller than the band gap value of the p-type doped layer. E.g., the n-type doped layer and the p-type doped layer are GaN layers, and each emissive layer is an InGaN layer.

The emissive layer is e.g. undoped. In other embodiments, the emissive layer is doped.

A quantum well is a specific example of an emissive layer having a band gap value smaller than the band gap values of the n-type and p-type doped layers.

Doping: Doping is defined as the presence, in a material, of impurities providing free charge carriers. Impurities are e.g. atoms of an element which is not naturally present in the material. When impurities increase the density of holes in the material, compared to the undoped material, the doping is p-type. E.g. a layer of gallium nitride, GaN, is p-type doped by adding magnesium atoms (Mg).

When the impurities increase the volume density of free electrons in the material, compared to the undoped material, the doping is n-type e.g. a layer of gallium nitride, GaN, is n-doped by adding silicon (Si) atoms.

Conversion Material: The conversion material is configured for converting the first radiation emitted by the light emitter into a second radiation. In other words, the conversion material is configured for being excited by the first radiation and for emitting the second radiation in response.

The second radiation has a second range of wavelengths. The second range is distinct from the first range. More particularly, the second place has a second average wavelength, the second average wavelength being different from the first average wavelength. The second average wavelength is, in particular, strictly greater than the first average wavelength.

The conversion material is e.g. a semiconductor material.

E.g., the conversion material is selected from the group consisting of: CdSe, CdTe, ZnSe, ZnTe, InP, InPZnS, Ag₂S, CulnS, CulnSe, AgInS₂, AgInSe₂, or further InPZnₓSe_{x-y}S_{y}. However, other types of materials are conceivable.

In other embodiments, the conversion material is a non-semiconductor material such as inorganic garnet. E.g. the conversion material is a doped yttrium-aluminum garnet. However, other types of non-semiconductor conversion materials, in particular other garnets, are conceivable.

More particularly, the conversion material can be an inorganic phosphorus.

Yttrium-aluminum garnet particles (e.g. YAG:CE), Terbium-aluminum garnet particles, TAG, (e.g. TAG:Ce), silicate particles (e.g. SrBaSiO4:Eu), sulfide particles (e.g. SrGa2S4:Eu, SrS: Eu, CaS:Eu, etc.), nitride particles (e.g. Sr2Si5N8:Eu, Ba2Si5N8:Eu, etc.), oxynitride particles (e.g. Ca-α-SiAlON:Eu, SrSi2O2N2:Eu, etc.), fluoride particles (e.g. K₂SiF6:Mn, Na2SIF6:Mn, etc.) are examples of inorganic phosphors.

Many other conversion materials can be used, such as doped aluminates, doped nitrides, doped fluorides, doped sulfides, or doped silicates.

The conversion material is e.g. doped with rare earth elements, alkaline earth elements or transition-metal elements. Cerium is e.g. sometimes used for doping yttrium-aluminum garnets.

The conversion material comprises e.g. a set of particles P made of the conversion material. The particles P are sometimes called “luminophores”.

Semiconductor material: The term “band gap value” should be understood as the band gap value between the valence band and the conduction band of the material.

The band gap value is e.g. measured in electron volts (eV).

Among the allowed energy bands for electrons in the material, the valence band is defined as the band which has the highest energy while being completely filled at a temperature less than or equal to 20 Kelvin (K).

A first energy level is defined for every valence band. The first energy level is the highest energy level in the valence band.

Among the allowed energy bands for electrons in the material, the conduction band is defined as the band which has the lowest energy while not being completely filled at a temperature of less than or equal to 20 K.

A second energy level is defined for every conduction band. The second energy level is the highest energy level in the conduction band.

Thus, every band gap value is measured between the first energy level and the second energy level of the material.

A semiconductor material is a material having a band gap value strictly greater than zero and less than or equal to 6.5 eV.

A direct band gap semiconductor is an example of a semiconductor material. A material is considered to have a “direct band gap” when the minimum of the conduction band and the maximum of the valence band correspond to the same value of the momentum of charge carriers. A material is considered to have an “indirect band gap” when the minimum of the conduction band and the maximum of the valence band correspond to different values of the momentum of charge carriers.

Each semiconductor material can be chosen e.g. from the group consisting of III-V semiconductors, in particular nitrides of [group-]III elements, II-VI semiconductors, or further IV-IV semiconductors.

III-V semiconductors include in particular InAs, GaAs, AlAs and the alloys thereof, InP, GaP, AIP and the alloys thereof, and the nitrides of elements III.

II-VI semiconductors include CdTe, HgTe, CdSe, HgSe, and the alloys thereof.

IV-IV semiconductors include in particular Si, Ge and the alloys thereof.

Nanowires: A nanowire is a particular example of a three-dimensional structure.

A three-dimensional structure is a structure which extends along a main direction. The three-dimensional structure has a length measured along the main direction. The three-dimensional structure also has a maximum lateral dimension measured along a lateral direction perpendicular to the main direction, the lateral direction being the direction perpendicular to the main direction along which the dimension of the structure is greatest.

The maximum lateral dimension is e.g. less than or equal to 10 micrometers (μm), and the length is greater than or equal to the maximum lateral dimension. The maximum lateral dimension is advantageously less than or equal to 2.5 μm.

The maximum lateral dimension is, in particular, greater than or equal to 10 nm.

In specific embodiments, the length is greater than or equal to twice the maximum lateral dimension, e.g. greater than or equal to five times the maximum lateral dimension.

The main direction is e.g. the normal direction D. In such case, the length of the three-dimensional structure is called the “height” and the maximum dimension of the three-dimensional structure, in a plane perpendicular to the normal direction D, is less than or equal to 10 μm.

The maximum dimension of the three-dimensional structure, in a plane perpendicular to the normal direction D, is often referred to as a “diameter” regardless of the cross-sectional shape of the three-dimensional structure.

Every three-dimensional structure is e.g. a microwire. A microwire is a three-dimensional cylindrical structure.

In a specific embodiment, the microwire is a cylinder extending along the normal direction D. The microwire is e.g. a cylinder with a circular base. In such case, the diameter of the base of the cylinder is less than or equal to half the length of the microwire.

A microwire with a maximum lateral dimension of less than 1 μm is called a “nanowire”.

A pyramid extending along the normal direction D from the substrate is another example of a three-dimensional structure.

A cone extending along the normal direction D is another example of a three-dimensional structure.

A truncated cone or a truncated pyramid extending along the normal direction D is yet another example of a three-dimensional structure.

Standing wave: A standing wave is the phenomenon resulting from the simultaneous propagation in opposite directions of a plurality of waves of the same frequency and of the same amplitude, in the same physical medium, which forms a figure the elements of which are fixed in time. Instead of seeing therein a propagating wave, a standing vibration of different intensity is observed at each observed point. The characteristic fixed points are called pressure nodes.

Pixels: Many display screens have a set of light emitters that are used for forming the image displayed on the screen. Such emitters each play the role of an image element or “pixel” from the English “Picture Element” (in particular when the screen is monochrome), or of a portion of such an image element, called “sub-pixel” (in particular when the screen is a color screen, each pixel including sub-pixels of different color the selective lighting of which allows the color of the pixel to be modified). In the description, the red pixel was, in the above sense, rather a subpixel.

Quantum well: A quantum well is a structure wherein quantum confinement occurs, in one direction, for at least one type of charge carrier. The effects of quantum confinement occur when the size of the structure along such direction becomes comparable to or smaller than the de Broglie wavelength of the carriers, which are usually electrons and/or holes, leading to energy levels called “energy sub-bands”.

In such a quantum well, carriers can only have discrete energy values but are generally apt to move within a plane perpendicular to the direction wherein the confinement occurs. The energy values available for carriers, also known as “energy levels”, increase as the quantum well dimensions decrease along the direction wherein the confinement occurs.

In quantum mechanics, the “De Broglie wavelength” is the wavelength of a particle when the particle is considered a wave. The de Broglie wavelength of electrons is also called “electron wavelength”. The de Broglie wavelength of a charge carrier depends on the material of which the quantum well is made.

An emissive layer, the thickness of which is strictly smaller than the product between the electron wavelength of the electrons in the semiconductor material forming the emissive layer, and five, is an example of a quantum well.

Another example of a quantum well is an emissive layer the thickness of which is strictly smaller than the product of the de Broglie wavelength of excitons in the semiconductor forming the emitting layer, and five. An exciton is a quasi-particle comprising an electron and a hole.

In particular, a quantum well often has a thickness comprised between 1 nm and 50 nm.

Radiation: Every radiation comprises a set of electromagnetic waves.

A wavelength is defined for every electromagnetic wave.

Every set corresponds to a range of wavelengths or to a spectral band. The wavelength range is the group consisting of the set of wavelengths of the set of electromagnetic waves.

An average wavelength for a spectral band can be defined as the average of the ends of the spectral band.

Red: red radiation has an average wavelength comprised between 600 nm and 720 nm.

Ultraviolet: ultraviolet radiation has an average wavelength comprised between 350 nm 430 nm.

Green: green radiation has an average wavelength comprised between 500 nm and 560 nm.

1. A light-emitting element including:
a conversion material suitable for converting a first radiation within a first spectral band into a second radiation within a second spectral band, the second spectral band being distinct from the first spectral band, and
a standing wave generator within the first spectral band, the standing wave generator including a two-dimensional photonic crystal suitable for generating a standing wave within the first spectral band, the photonic crystal being formed at least in part by light-emitting diodes suitable for emitting within the first spectral band.

2. The light-emitting element according to claim 1, wherein the photonic crystal is formed solely by light-emitting diodes and a medium surrounding the light-emitting diodes.

3. The light-emitting element according to claim 1, wherein the light-emitting diodes comprise an active layer at least one active layer being included in the photonic crystal.

4. The light-emitting element according to claim 3, wherein the photonic crystal is partly formed from each active layer of the light-emitting diodes.

5. The light-emitting element according to claim 1, wherein the photonic crystal includes all of each light-emitting diode.

6. The light-emitting element according to claim 1, wherein the light-emitting diodes are in a medium, said medium being the conversion material.

7. The light-emitting element according to claim 1, wherein the conversion material is on the photonic crystal.

8. The light-emitting element according to claim 1, wherein the photonic crystal has a plurality of band gaps, the photonic crystal having a pitch and a filling factor suitable for making the light-emitting diodes to emit at 90° on the band edge of the first band gap.

9. The light-emitting element according to claim 1, wherein the photonic crystal has a plurality of band gaps, the photonic crystal having a pitch and a filling factor suitable for making the light-emitting diodes emit at 90° on the band edge of a band gap which is different from the first band gap.

10. The light-emitting element according to claim 9, the pitch and the filling factor of the photonic crystal are also suitable for making the conversion material emit on the band edge of a 0° band gap, the band gap wherein the conversion material emits being smaller than the band gap wherein the light-emitting diodes emit.

11. The light-emitting element according to claim 1, wherein the photonic crystal is surrounded by walls forming a cavity, at least one of the walls being made of a material selected from the list consisting of a transparent conductive oxide such as indium tin oxide or a zinc oxide doped with gallium or aluminum, a metal such as Ag or Al, graphene and a combination of said elements.

12. The light-emitting element according to any claim 1, wherein the conversion material is a polymer matrix comprising quantum dots.

13. The light-emitting element according to claim 1, wherein each light-emitting diode includes an active medium made of a first material surrounded by layers made of a second material, the first material comprising InGaN, and the second material comprising GaN.

14. The light-emitting element according to claim 1, wherein the photonic crystal has a central part and a peripheral part, each part bringing together a plurality of light-emitting diodes, only the central part of the photonic crystal being supplied with energy.

15. An optoelectronic device comprising at least one light-emitting element according to claim 1.
